(19) United States
(12) Patent Application Publication
(10) Pub. No.: US 2017/0085840 A1
(43) Pub. Date: Mar. 23, 2017

(54) INFORMATION GATHERING APPARATUS AND METHOD FOR GATHERING INFORMATION IN AIR

(71) Applicant: CASIO COMPUTER CO., LTD., Tokyo (JP)

(72) Inventors: Takahiro MIZUSHINA, Kawagoe-shi (JP); Shunsuke YAMADA, Tokyo (JP); Toshihiro TAKAHASHI, Tokyo (JP); Hideaki MATSUDA, Tokyo (JP)

(73) Assignee: CASIO COMPUTER CO., LTD., Tokyo (JP)

(21) Appl. No.: 15/218,635

(22) Filed: Jul. 25, 2016

(30) Foreign Application Priority Data
Sep. 18, 2015 (JP) 2015-185984

(51) Int. Cl. H04N 7/18; B64D 47/08; B64C 39/02; G06F 3/044; H04N 5/225

(52) U.S. Cl. CPC H04N 7/185; G06F 3/044; H04N 5/2257; B64C 39/024; B64D 47/08; B64C 2201/127

(57) ABSTRACT

An information gathering apparatus includes an information acquisition sensor unit to acquire information and a propelling system to fly in air. The information gathering apparatus includes a supporting unit and a controller. The supporting unit supports the propelling system in the first and second configurations. The controller moves the supporting unit such that the supporting unit supports the propelling system in the second configuration after the information gathering apparatus is thrown up in a state where the supporting unit supports the propelling system in the first configuration.

### CROSS-REFERENCE TO RELATED APPLICATION

This application is based upon and claims the benefit of priority under 35 USC 119 of Japanese Patent Application No. 2015-185984 filed on Sep. 18 2015 the entire disclosure of which, including the description, claims, drawings, and abstract, is incorporated herein by reference in its entirety.

### BACKGROUND OF THE INVENTION

1. Field of the Invention

The present invention relates to an information gathering apparatus for performing information gathering, such as imaging, in the air.

2. Description of the Related Art

Imaging apparatuses configured by attaching digital cameras to small pilotless aircrafts referred to collectively as so-called drones have started to spread (see JP-B-5432277 and JP-A-2013-129301 for instance). The small pilotless aircraft each has, for example, four propelling devices using rotor blades configured to be driven by motors, and the aircrafts and the digital cameras are operated by timers or are remotely controlled in various manners such as a wireless manner, thereby performing imaging from higher inaccessible positions.

Meanwhile, there have also been proposed imaging apparatuses each of which is configured by mounting a plurality of cameras on a spherical object having no propelling device (see U.S. Pat. No. 8,237,787 and JP-A-2013-066086 for instance). If a user throws up the spherical object with a hand, the plurality of cameras panoramically images, for example, the ground side, or recognizes and images the user.

### SUMMARY OF THE INVENTION

According to an aspect, an information gathering apparatus includes an information acquisition sensor unit to acquire information and a propelling system to fly in air. The information gathering apparatus includes a supporting unit and a controller. The supporting unit supports the propelling system in the first and second configurations. The controller moves the supporting unit such that the supporting unit supports the propelling system in the second configuration after the information gathering apparatus is thrown up in a state where the supporting unit supports the propelling system in the first configuration.

According to another aspect, an information gathering apparatus includes an information acquisition sensor unit to acquire information and a propelling system to fly in air. The information gathering apparatus includes a supporting unit, a contact detecting unit and a controller. The supporting unit supports the propelling system in first and second configurations. The controller moves the supporting unit such that the supporting unit supports the propelling system in the second configuration after the contact detecting unit detects that a hand is separated from the contact detecting unit and the information gathering apparatus is thrown up.

According to another aspect, a method of an information gathering apparatus including a supporting unit, an information acquisition sensor unit to acquire information and a propelling system configured to fly in air, including: detecting whether the information gathering apparatus is thrown up; transforming the supporting unit from a storage configuration into a flight configuration when the detecting step detects that the information gathering apparatus is thrown up; and moving the propelling system such that the information gathering apparatus flies when the supporting unit is in the flight configuration.

### BRIEF DESCRIPTION OF THE DRAWINGS

FIG. 1A is a view illustrating an example of the structure of motor frames of an imaging apparatus according to an embodiment in a state where the motor frames are open.

FIG. 1B is a view illustrating the example of the structure of the motor frames of the imaging apparatus according to the embodiment in a state where the motor frames are closed.

FIG. 2A is a view illustrating an example of the structure of finger guards of the imaging apparatus according to the embodiment in a state where the finger guards are open.

FIG. 2B is a view illustrating the example of the structure of the finger guards of the imaging apparatus according to the embodiment in a state where the finger guards are closed.

FIG. 3 is a view illustrating an example of the structure of a touch sensor on a finger guard.

FIG. 4 is a view illustrating an example of the system configuration of the imaging apparatus according to the embodiment.

FIG. 5A is an explanatory view illuminating the operation of the motor frames, and shows the closed state.

FIG. 5B is another explanatory view illustrating the operation of the motor frames, and shows the motor frames are being opened.

FIG. 5C is a further explanatory view illustrating the operation of the motor frames, and shows the open state.

FIG. 6 is a flow chart illustrating an example of a control process of the imaging apparatus according to the embodiment.

FIG. 7 is a view illustrating examples of variations in acceleration outputs.

### DETAILED DESCRIPTION OF EMBODIMENTS

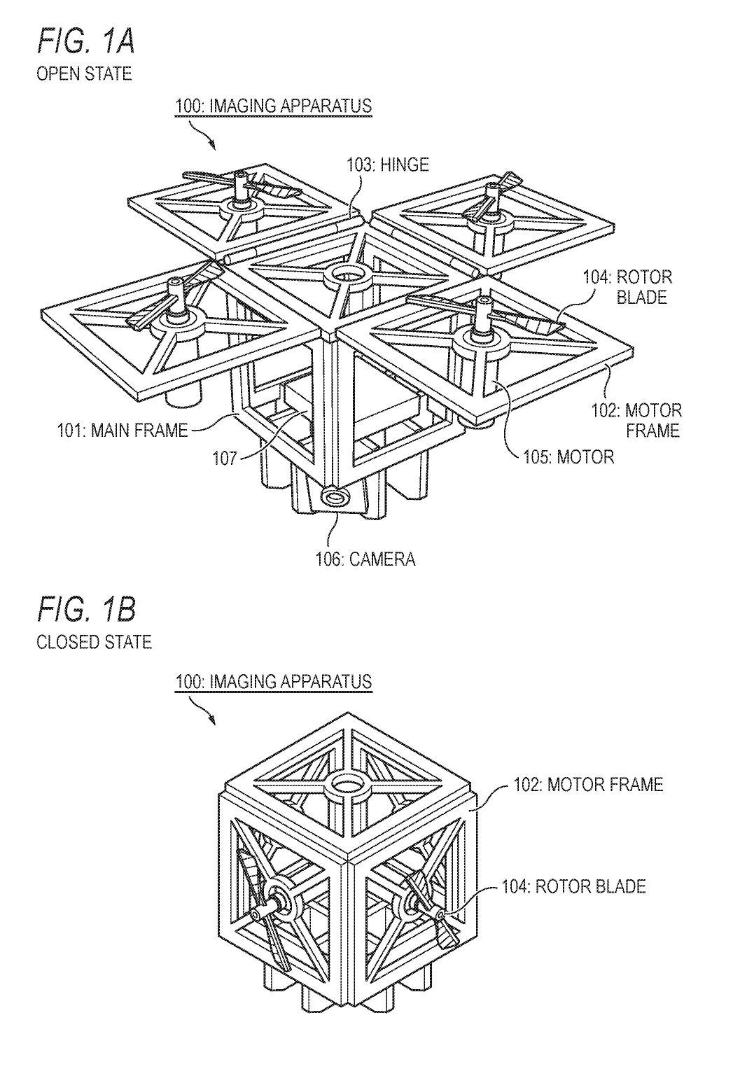

Hereinafter, an embodiment of the present invention will be described in detail with reference to the accompanying drawings. FIG. 1 is a view illustrating an example of the structure of motor frames of an imaging apparatus 100 which is an example of an information gathering apparatus according to the present embodiment.

Four motor frames (supporting units) 102 are attached to a main frame 101 by hinges 103, respectively. The motor frames 102 are configured to be able to support motors 105, and rotor blades 104 are fixed on the motor shafts of the motors 105. The four pairs of motors 105 and rotor blades 104 constitute propelling systems.

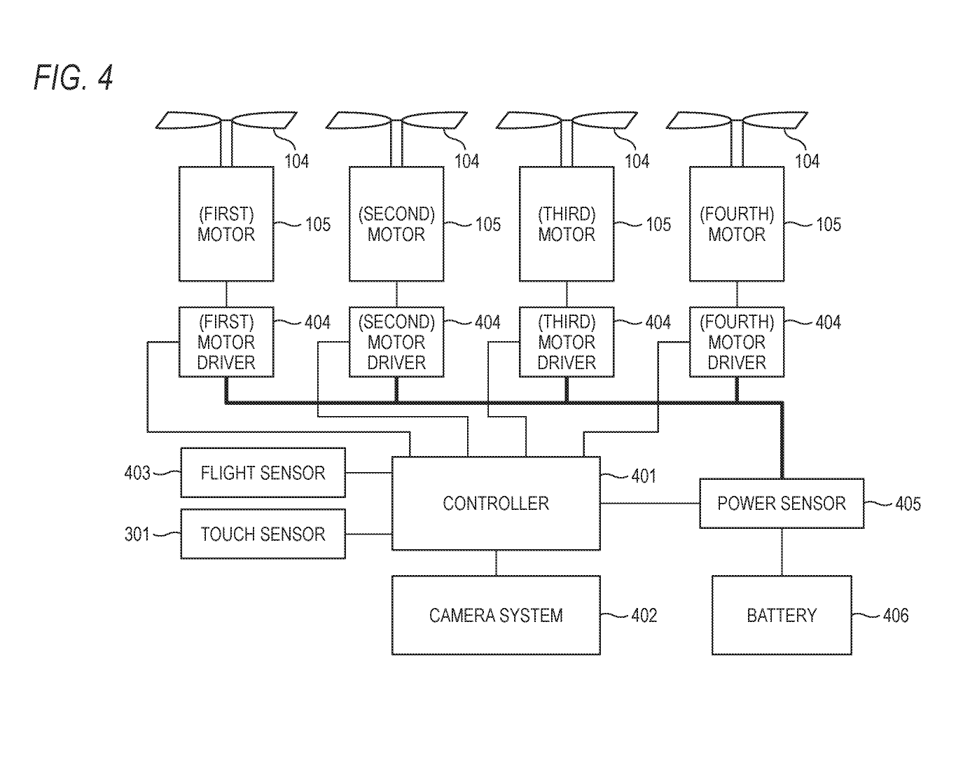

On the lower portion of the main frame 101, as an example of an information acquisition sensor unit, a camera 106 which is an imaging device is attached. Inside the main frame 101, various control devices (to be described below with reference to FIG. 4) are stored.

The hinges 103 joining the motor frames 102 and the main frame 101 are configured to be rotatable in an angle range from 0° to 90° such that transformation to an “open state” (a second configuration, for example, a flight configuration) of FIG. 1A suitable for flying or a “closed state” (a first configuration, for example, a storage configuration) of FIG. 1B suitable for throwing the imaging apparatus up is possible.

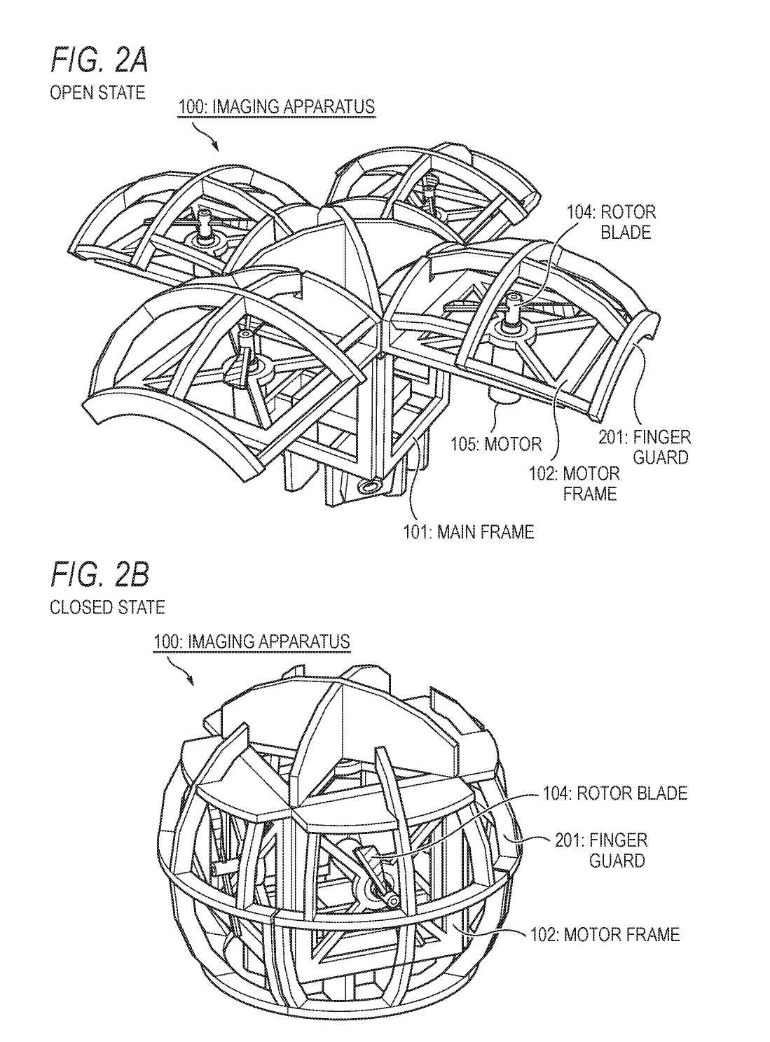

FIG. 2 is a view illustrating an example of the structure of finger guards of the imaging apparatus 100 according to the present embodiment. Although not shown in FIG. 1 in order to simplify the explanation thereof, as shown in FIG. 2, finger guards 201 are attached so as to cover the motor frames 102, thereby keeping the body of a user, such as the fingers of a hand throwing the imaging apparatus up, from coming into contact with any portions of the rotor blades 104 supported by the motor frames 102.

Also, on the finger guards 201, electrodes are attached as touch sensors 301 capable of detecting that the finger guards 201 are being held by a hand. FIG. 4 is a view illustrating an example of the structure of the touch sensors 301 attached on the finger guards 201. The touch sensors 301 are formed as very thin electrodes on the outermost portions of the finger guards 201. Since their surfaces are insulated, if a hand 302 approaches them, electrostatic capacitance 303 increases, whereby the touch sensors detect whether the finger guards 201 are being held in the hand 302. Since the touch sensors 301 are formed on the outermost portions of the finger guards 201, the touch sensors can surely discriminate between the motion of a hand for throwing the imaging apparatus up and a state where the imaging apparatus has been actually separated from the hand and is falling freely. Alternatively, the touch sensors 301 may be implemented as mechanisms having a certain switch function, other than electrodes.

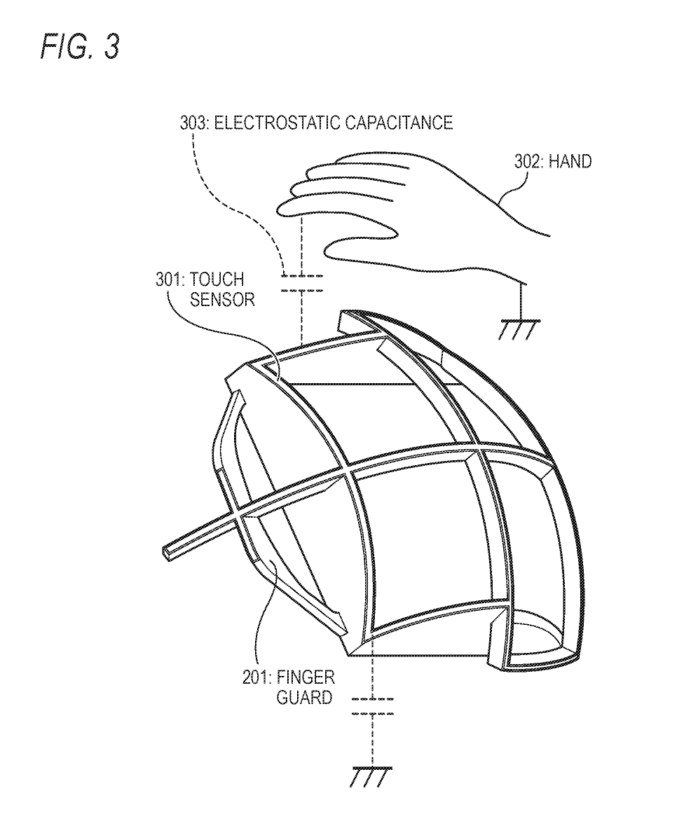

FIG. 4 is a view illustrating an example of the system configuration of the imaging apparatus 100 according to the present embodiment having the structure shown in FIGS. 1 to 3. A controller 401 is connected to a camera system 402 including the camera 106 (see FIG. 4), a flight sensor 403 which is composed of various components such as acceleration sensors, a gyroscope, and a GPS (global position system) sensor, the touch sensors 301 of FIG. 3, first to fourth motor drivers 404 which drive the first to fourth motors 105 (see FIG. 1), respectively, and a power sensor 405 which supplies electric power to the individual motor drivers 404 while monitoring the voltage of a battery 406. Also, although not particularly shown, electric power of the battery 406 is also supplied to various control units for the controller 401, the camera system 402, the flight sensor 403, the motor drivers 404, the power sensor 405, and the touch sensors 301. The controller 401 acquires information on the posture of the airframe of the imaging apparatus 100 from the flight sensor 403 in real time. Also, the controller 401 uses the power sensor 405 to transmit power instruction signals to the first to fourth motor drivers 404 while monitoring the voltage of the battery 406. The power instruction signals depend on duty ratios based on pulse width modulation of the first to fourth motor drivers, respectively. As a result, the first to fourth motor drivers 404 control the rotation speeds of the first to fourth motors 105, respectively. Also, the controller 401 controls the camera system 402, thereby controlling an imaging operation of the camera 106 (FIG. 1).

The controller 401, the camera system 402, the flight sensor 403, the motor drivers 404, the power sensor 405, and the battery 406 shown in FIG. 4 are mounted in a casing 107 in the main frame 101 of FIG. 1.

Operations of the imaging apparatus 100 according to the present embodiment and having the above described configuration will be described below. In the present embodiment, the motor frame 102 can hold the propelling systems composed of the motors 105 and the rotor blades 104, in two configurations of the “closed state” (the first configuration, for example, the storage configuration) suitable for throwing the imaging apparatus up and shown in FIG. 1B or 2B and the “open state” (the second configuration, for example, the flight configuration) suitable for flying and shown in FIG. 1A or 2A. Therefore, when the airframe of the imaging apparatus 100 is in the “closed state”, the user can throw the airframe up into the air, like a ball. Thereafter, when the imaging apparatus starts to fall down, under control of the controller 401 of FIG. 4, the airframe of the imaging apparatus 100 can transform to the “open state”, thereby becoming a flight state, such as hovering, and then perform imaging by the camera 106. Therefore, due to the finger guards 201 preventing the user from coming into contact with the rotor blades 104, the user can safely throw up the airframe of the imaging apparatus 100, like a ball, and can make the imaging apparatus perform a high-altitude flight and an imaging operation using the propelling systems.

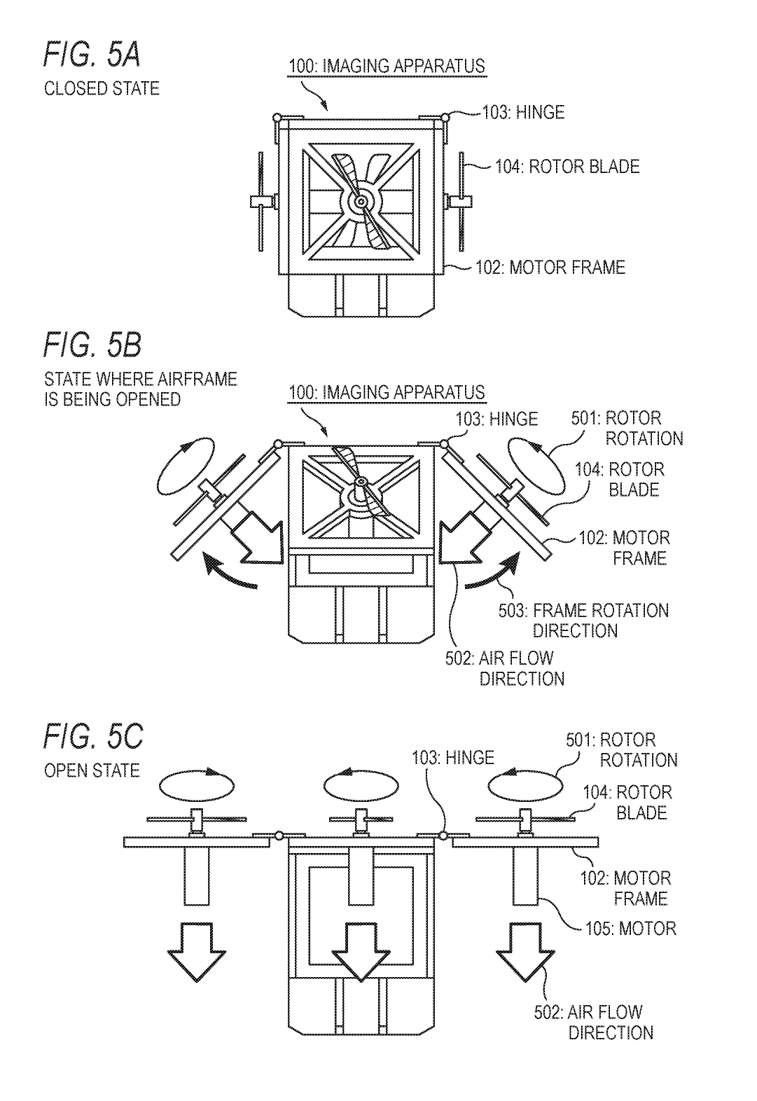

FIG. 5 is an explanatory view illustrating the operation of the motor frames 102. When the motors 105 (FIG. 1) are not rotating, the imaging apparatus 100 keeps the “closed state” shown in FIG. 5A. If the user throws the closed imaging apparatus 100 up into the air, the controller 401 of FIG. 4 detects the timing when the imaging apparatus starts to fall down, and starts to rotate the first to fourth motors 105 through the first to fourth motor drivers 404, as will be described below. As a result, the first to fourth motors 105 start to rotate as shown by a reference symbol “501” in FIG. 5B, whereby air is pushed out in the directions of air flow arrows 502. At this time, the reaction force (lift force) causes the motor frames 102 attached to the main frame 101 by the hinges 103 so as to be rotatable, to rotate in the directions of frame rotation direction arrows 503, whereby the imaging apparatus 100 transforms from the state of FIG. 5B to the “open state” of FIG. 5C. At this time, if the “open state” can be maintained at rotation speeds of the motors 105 sufficiently lower than their maximum rotation speeds, the motor frames 102 can be regulated at the positions to which they have rotated by 90°, by the hinges 103, whereby the “open state” of FIG. 5C is kept. Also, in the hinges 103, leaf springs may be assembled as locking mechanisms for holding the “open state”. In this case, even though the rotation speeds of the rotor blades 104 vary, it is possible to surely keep the “open state”. In the “open state”, the directions of the air flow arrows 502 become directions shown in FIG. 5C, and therefore, the imaging apparatus can stably fly by rotation of the four rotor blades 104.

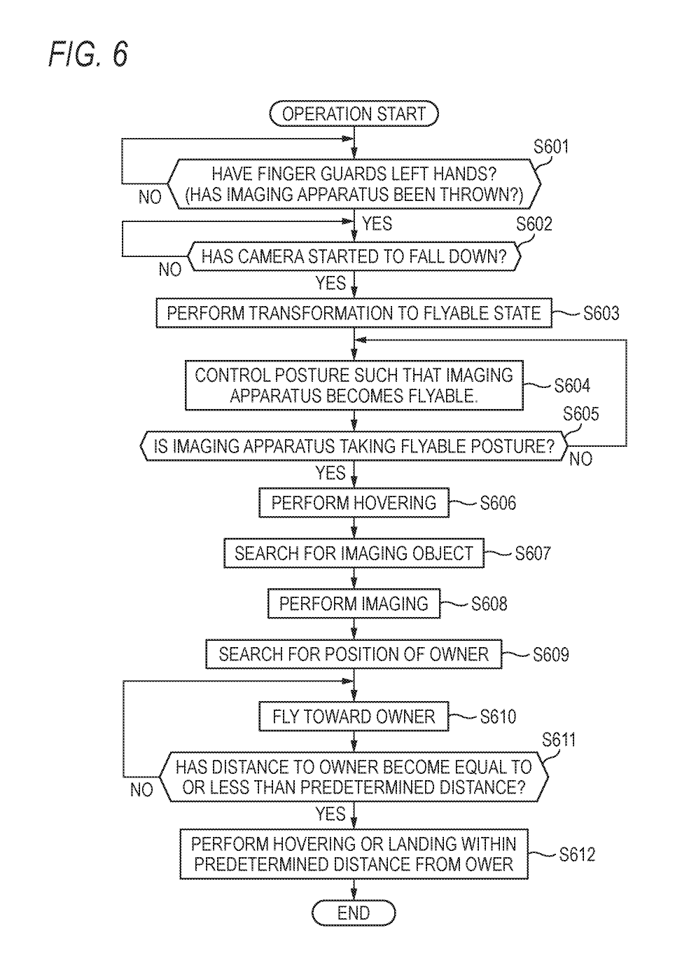

FIG. 6 is a flow chart illustrating an example of a control process of the imaging apparatus 100 according to the present embodiment. This process can be implemented in the controller 401 of FIG. 4 as a process in which a central processing unit (CPU) included in the controller executes a control program stored in a memory (not particularly shown) included in the controller.

First, in STEP S601, the controller 401 monitors variations in the voltages of the touch sensors 301 formed on the finger guards 201 of FIG. 2, thereby monitoring whether the finger guards 201 have been separated from a hand of the user (whether the airframe has been thrown). If the determination result of STEP S601 is “NO”, the controller repeats STEP S601.

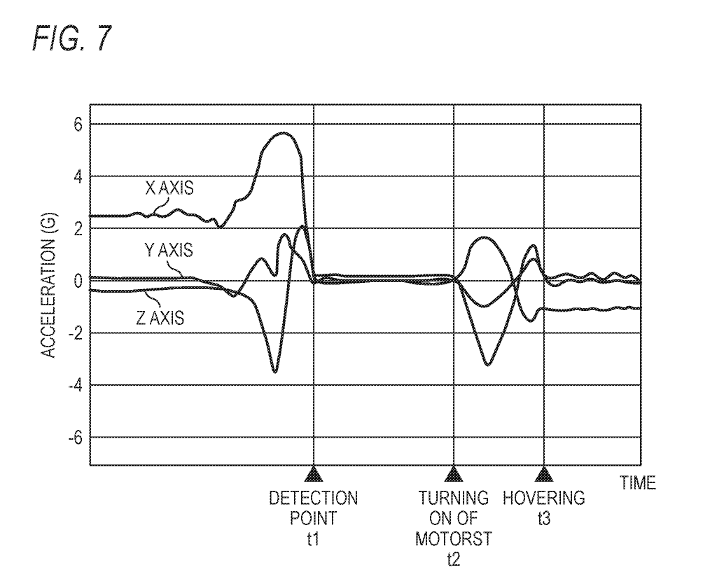

If the determination result of STEP S601 becomes “YES”, in STEP S602, the controller 401 monitors variations in acceleration values in three directions of an x axis, a y axis, and a z axis output from the flight sensor 403, thereby monitoring whether the airframe of the imaging apparatus 100 has transitioned from a rising state to a falling state. If the determination result of STEP S602 is “NO”, the controller repeats STEP S602. FIG. 7 is a view illustrating examples of variations in the acceleration outputs of the flight sensor 403. The vertical axis represents the value of acceleration, and the horizontal axis represents time, and the flight sensor 403 outputs acceleration values in three directions of the x axis, the y axis, and the z axis, as described above. Since the flight sensor 403 is mounted in the casing 107 in the main frame 101 of FIG. 1, when the imaging apparatus is still, the acceleration of gravity is detected in the vertical direction. However, if the user throws the imaging apparatus with a hand, according to the motion of the hand, acceleration is detected in each of the x axis, the y axis, and the z axis. In a case where the imaging apparatus becomes slow and the lift-to-drag ratio becomes very small, it can be considered that external force has not been applied after the moment when the imaging apparatus was separated from the hand. Therefore, regardless of the direction of the imaging apparatus, the imaging apparatus transitions to a falling state, and the flight sensor 403 attached to the airframe of the imaging apparatus 100 which is a falling object outputs acceleration values around 0. The controller 401 detects such time point t1 as a point when it is detected that the image processing has been separated from the hand. Further, in order to prevent malfunctions, the controller 401 determines a time point t2 after a predetermined period when the acceleration values are kept around 0, as a time point when the camera starts to fall down in the air. Actually, there is air resistance although it is little, and the acceleration values do not become exactly 0. For this reason, for example, a range between −0.1 g and +0.1 g around 0 is set as a determination range. Also, these values around 0 are examples. Actual values around 0 depend on the structure of the airframe of the imaging apparatus 100, and thus are set to appropriate values in terms of adjustment.

If the determination result of STEP S602 becomes “YES”, in STEP S603, the controller 401 turns on the first to fourth motors 105 through the first to fourth motor drivers 404. As a result, the motor frame 102 transforms from the “closed state” of FIG. 5A to the “open state” of FIG. 5C through the transient state of FIG. 5B.

Thereafter, in STEP S604, the controller 401 performs a posture control operation such that the imaging apparatus becomes flyable. Then, in STEP S605, based on the outputs of the flight sensor 403, the controller determines whether the imaging apparatus is taking a flyable posture. If the determination result of STEP S605 is “NO”, the controller repeats STEP S604.

If the determination result of STEP S605 becomes “YES”, in STEP S606, the controller 401 controls the first to fourth motor drivers 404, thereby maintaining the airframe of the imaging apparatus 100 in the hovering state.

Subsequently, in STEP S607, the controller 401 searches for an imaging object. As the searching method, it is possible to use an existing technology. As an example, the controller 401 compares GPS data (latitude/longitude data) transmitted from a communication device held by the user who threw up the imaging apparatus, with GPS data of the airframe output from the flight sensor 403, thereby calculating the positional relation between the airframe and the user, and controls the camera system 402, thereby turning the camera 106 toward the user. As another example, the controller 401 controls the camera system 402, thereby imaging the ground side by the camera 106, and if somebody is detected, the controller locks the camera 106 in that direction. As a further example, the controller 401 controls the camera system 402, thereby turning the camera 106 in a random direction toward the ground side.

If any imaging object is found, in STEP S608, the controller 401 controls the camera 106 through the camera system 402, such that the camera performs imaging, thereby obtaining image data. The controller 401 stores the image data in the internal memory of the controller 401. Alternatively, the controller 401 transmits the image data to a terminal device of the user who threw up the imaging apparatus, by wireless communication.

If imaging is performed for a predetermined period or a predetermined number of times, or imaging finishes in response to an instruction from the user, in STEP S609, the controller 401 searches for the location of the user (the owner) who threw up the imaging apparatus. As this searching method, similarly in the case of STEP S607, it is possible to use an existing technology.

If the location of the owner is found, in STEP S610, the controller 401 controls the first to fourth motor drivers 404 such that the imaging apparatus flies toward the owner. Then, in STEP S611, based on GPS data and the like, the controller determines whether the distance from the owner is equal to or less than a predetermined distance. If the determination result of STEP S611 is “NO”, the controller repeats STEP S610.

If the determination result of STEP S611 becomes “YES”, in STEP S612, the controller 401 controls the first to fourth motor drivers 404 such that the motor drivers perform a hovering operation or a landing operation within the predetermined distance from the owner. In a case where a landing operation is performed, the controller stops the first to fourth motors, and finishes the control operation.

Although the embodiment of the imaging apparatus 100 having the camera 106 as the information acquisition sensor unit has been described as an example of the information gathering apparatus, the present invention is not limited thereto, and may be embodied, for example, as an information gathering apparatus having a sensor for gathering information on temperature distribution or atmospheric component distribution, as the information acquisition sensor unit.

Also, although the example in which the propelling systems include the motors 105 and the rollers 17 has been described, a propelling system may be implemented by a mechanism which is driven by air pressure or engine power.

Further, although the motor frames 102 having a cubic or rectangular parallelepiped storage configuration as the first configuration has been described as the supporting units, the first configuration is not limited thereto. Also, the flight configuration which is an example of the second configuration is not limited to the “open state” as shown in FIG. 1A or 2A.

The finger guards 201 of FIG. 2 configured as described above are not essential for the present invention.

Although some embodiments of the present invention have been described above, those embodiments are merely illustrative and do not limit the technical range of the present invention. The present invention can take other various embodiments, and various modifications such as omission and replacement can be made without departing the gist of the present invention. These embodiments and modifications are included in the scope and gist of the invention described in this specification and the like, and are included in the scope of the inventions disclosed in claims and their equivalents.

What is claimed is:

1. An information gathering apparatus including an information acquisition sensor unit configured to acquire information and a propelling system configured to fly in air, comprising:
a supporting unit that supports the propelling system in the first and second configurations; and
a controller that moves the supporting unit such that the supporting unit supports the propelling system in the second configuration after the information gathering apparatus is thrown up in a state where the supporting unit supports the propelling system in the first configuration.

2. The information gathering apparatus according to claim 1, wherein:
the first configuration is a storage configuration when the information gathering apparatus is thrown up, and the second configuration is a flight configuration when the information gathering apparatus flies.

3. The information gathering apparatus according to claim 2, further comprising:
a flight sensor unit that controls flight,
wherein the controller drives the propelling system while the controller controls the first and second configurations based on an output of the flight sensor unit.

4. The information gathering apparatus according to claim 1, further comprising:
a touch sensor unit,
wherein the controller detects that the information gathering apparatus is separated from a finger of a user and is thrown up, based on an output of the touch sensor unit.

5. The information gathering apparatus according to claim 4, wherein:
the touch sensor unit is formed on an outermost portion of the information gathering apparatus.

6. The information gathering apparatus according to claim 5, wherein:
the touch sensor unit is formed on the outermost portion regardless of whether the supporting unit supports the propelling system in the first configuration or in the second configuration.

7. The information gathering apparatus according to claim 1, further comprising:
a finger guard that covers the supporting unit and that keeps a user from coming into contact with drive portions of the propelling system; and
a touch sensor unit that is on a portion of the finger guard where a finger of the user comes into contact with,
wherein, based on an output of the touch sensor unit, the controller detects that the finger is separated from the touch sensor unit and the information gathering apparatus is thrown up.

8. The information gathering apparatus according to claim 3, wherein:
after the information gathering apparatus is thrown up, when the flight sensor unit detects that acceleration becomes about zero, the controller moves the supporting unit such that the supporting unit supports the propelling system in the flight configuration.

9. The information gathering apparatus according to claim 2, wherein:
after the information gathering apparatus is thrown up, the controller drives the propelling system to move the supporting unit such that the supporting unit supports the propelling system in the flight configuration.

10. The information gathering apparatus according to claim 2, wherein:
the supporting unit has a locking part which fixes the flight configuration after the propelling system is in the flight configuration.

11. The information gathering apparatus according to claim 1, wherein:
the information acquisition sensor unit includes a digital camera system and the digital camera system takes at least a still image or a moving image.

12. The information gathering apparatus according claim 1, wherein:
the propelling system include a plurality of units;
each unit includes a motor and a rotor blade which is rotated by the motor.

13. An information gathering apparatus including an information acquisition sensor unit configured to acquire information and a propelling system to fly in air, comprising:
a supporting unit that supports the propelling system in first and second configurations;
a contact detecting unit; and
a controller that moves the supporting unit such that the supporting unit supports the propelling system in the second configuration after the contact detecting unit detects that a hand is separated from the contact detecting unit and the information gathering apparatus is thrown up.

14. The information gathering apparatus according to claim 13, wherein:
the contact detecting unit is formed on an outermost portion of the information gathering apparatus regardless of whether the supporting unit supports the propelling system in the first configuration or the second configuration.

15. A method of an information gathering apparatus including a supporting unit, an information acquisition sensor unit configured to acquire information and a propelling system configured to fly in air, the method comprising:
detecting whether the information gathering apparatus is thrown up;
transforming the supporting unit from a storage configuration into a flight configuration when the detecting step detects that the information gathering apparatus is thrown up; and
moving the propelling system such that the information gathering apparatus flies when the supporting unit is in the flight configuration.
